(19) United States
(12) Patent Application Publication
(10) Pub. No.: US 2025/0218735 A1
(43) Pub. Date: Jul. 3, 2025

(54) GAS SPRAYING APPARATUS AND SUBSTRATE TREATING APPARATUS INCLUDING THE SAME

(71) Applicant: SEMES CO., LTD., Cheonan-si (KR)

(72) Inventors: Si Young JO, Chungcheongnam-do (KR); Je Hee LEE, Gyeonggi-do (KR)

(73) Assignee: SEMES CO., LTD., Cheonan-si (KR)

(21) Appl. No.: 18/937,627

(22) Filed: Nov. 5, 2024

(30) Foreign Application Priority Data
Dec. 28, 2023 (KR) 10-2023-0193927

(51) Int. Cl. H01J 37/32

(52) U.S. Cl. CPC H01J 37/32477; H01J 37/3244; H01J 37/32715; H01J 2237/022; H01J 2237/2007

(57) ABSTRACT

A gas spraying apparatus spraying a gas to prevent a polymer from being deposited on a surface of an electro-static chuck, and a substrate treating apparatus including the same are provided. The substrate treating apparatus comprises a chamber housing; an electro-static chuck supporting the substrate; a showerhead unit providing a first gas to an inner space of the chamber housing; a plasma generating unit generating plasma for treating the substrate by using the first gas; and a gas spraying apparatus for spraying a second gas from a surface of the electro-static chuck to the inner space, wherein the electro-static chuck includes: a first plate; a second plate disposed on the first plate; and an adhesive layer bonding the first plate and the second plate to each other, and the gas spraying apparatus sprays the second gas through an outlet formed between the first plate and the adhesive layer.

### CROSS-REFERENCE TO RELATED APPLICATION

This application claims priority from Korean Patent Application No. 10-2023-0193927 filed on Dec. 28, 2023 in the Korean Intellectual Property Office and all the benefits accruing therefrom under 35 U.S.C. 119, the contents of which in its entirety are herein incorporated by reference.

### BACKGROUND

### Technical Field

The present disclosure relates to a gas spraying apparatus applied to a facility for treating a substrate by using plasma, and a substrate treating apparatus including the same.

### Description of the Related Art

When a substrate is treated using plasma, an electro-static chuck (ESC) may be used to fix a position of the substrate inside a process chamber. The electro-static chuck may adsorb the substrate by using an electro-static force to fix the position of the substrate.

However, while the substrate is being treated, a polymer may be generated inside the process chamber due to plasma. The polymer may be deposited on a surface of the electro-static chuck. For this reason, heat efficiency of the electro-static chuck may be deteriorated, and various structural and functional problems may occur.

### BRIEF SUMMARY

An object of the present disclosure is to provide a gas spraying apparatus spraying a gas to prevent a polymer from being deposited on a surface of an electro-static chuck, and a substrate treating apparatus including the same.

The objects of the present disclosure are not limited to those mentioned above and additional objects of the present disclosure, which are not mentioned herein, will be clearly understood by those skilled in the art from the following description of the present disclosure.

A substrate treating apparatus according to one aspect of the present disclosure devised to achieve the above objects comprises a chamber housing providing a space in which a substrate is treated; an electro-static chuck supporting the substrate; a showerhead unit providing a first gas to the space; a plasma generating unit generating plasma for treating the substrate by using the first gas; and a gas spraying apparatus for spraying a second gas from a surface of the electro-static chuck to an inner space of the chamber housing, wherein the electro-static chuck includes: a first plate; a second plate disposed on the first plate; and an adhesive layer bonding the first plate and the second plate to each other, and the gas spraying apparatus sprays the second gas through an outlet formed between the first plate and the adhesive layer.

A gas spraying apparatus according to one aspect of the present disclosure devised to achieve the above objects is provided in a substrate treating apparatus together with an electro-static chuck including a first plate, a second plate disposed on the first plate, and an adhesive layer bonding the first plate and the second plate to each other, and comprises a gas supply unit providing a second gas different from a first gas used to treat the substrate; and a gas supply line connected to the gas supply unit, moving the second gas, wherein the gas spraying apparatus sprays the second gas to an inner space of the substrate treating apparatus through an outlet formed between the first plate and the adhesive layer.

A substrate treating apparatus according to another aspect of the present disclosure devised to achieve the above objects comprises a chamber housing providing a space in which a substrate is treated; an electro-static chuck supporting the substrate; a showerhead unit providing a first gas to the space; a plasma generating unit generating plasma for treating the substrate by using the first gas; and a gas spraying apparatus for spraying a second gas from a surface of the electro-static chuck to an inner space of the chamber housing, wherein the electro-static chuck includes: a first plate; a second plate disposed on the first plate; and an adhesive layer bonding the first plate and the second plate to each other, the gas spraying apparatus includes: a gas supply unit providing the second gas; and a gas supply line connected to the gas supply unit, moving the second gas and including a first outlet formed between the first plate and the adhesive layer and a second outlet formed on a surface of the first plate, the gas spraying apparatus sprays the second gas through the first outlet and the second outlet, and the second gas is an inert gas.

Details of the other embodiments are included in the detailed description and drawings.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exemplary plan view illustrating an internal structure of a semiconductor manufacturing facility according to the first embodiment;

FIG. 2 is an exemplary plan view illustrating an internal structure of a semiconductor manufacturing facility according to the second embodiment;

FIG. 3 is an exemplary plan view illustrating an internal structure of a semiconductor manufacturing facility according to the third embodiment;

FIG. 4 is an exemplary cross-sectional view illustrating an internal structure of a substrate treating apparatus according to the first embodiment;

FIG. 5 is an exemplary cross-sectional view illustrating an internal structure of a substrate treating apparatus according to the second embodiment;

FIG. 6 is an exemplary cross-sectional view illustrating an internal structure of a substrate treating apparatus according to the third embodiment;

FIG. 7 is an exemplary view illustrating a gas spraying apparatus according to the first embodiment of the present disclosure;

FIG. 8 is an exemplary view illustrating a gas spraying apparatus according to the second embodiment of the present disclosure;

FIG. 9 is an exemplary view illustrating a gas spraying apparatus according to the third embodiment of the present disclosure;

FIG. 10 is an exemplary view illustrating a gas spraying apparatus according to the fourth embodiment of the present disclosure;

FIG. 11 is a first exemplary view illustrating an effect of a gas spraying apparatus according to the first embodiment of the present disclosure;

FIG. 12 is a second exemplary view illustrating an effect of a gas spraying apparatus according to the first embodiment of the present disclosure;

FIG. 13 is a first exemplary view illustrating a gas spraying apparatus according to the fifth embodiment of the present disclosure; and

FIG. 14 is a second exemplary view illustrating a gas spraying apparatus according to the fifth embodiment of the present disclosure.

### DETAILED DESCRIPTION OF THE DISCLOSURE

Hereinafter, the embodiment of the present disclosure will be described in detail with reference to the accompanying drawings. The same reference numerals will be used for the same elements on the drawings, and their redundant description will be omitted.

The present disclosure relates to a substrate treating apparatus for treating a substrate by using plasma and a semiconductor manufacturing facility including a plurality of substrate treating apparatuses. The substrate treating apparatus may include a gas spraying apparatus for spraying a gas. The gas spraying apparatus may prevent a polymer from being deposited on a surface of an electro-static chuck (ESC). Hereinafter, the substrate treating apparatus and the semiconductor manufacturing facility will be first described, and then the gas spraying apparatus will be described.

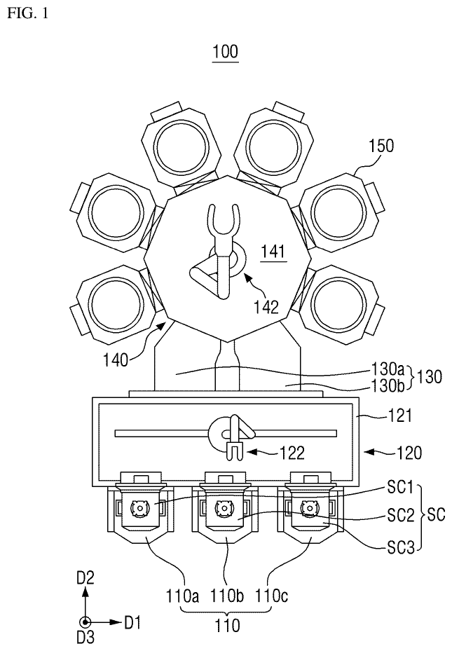

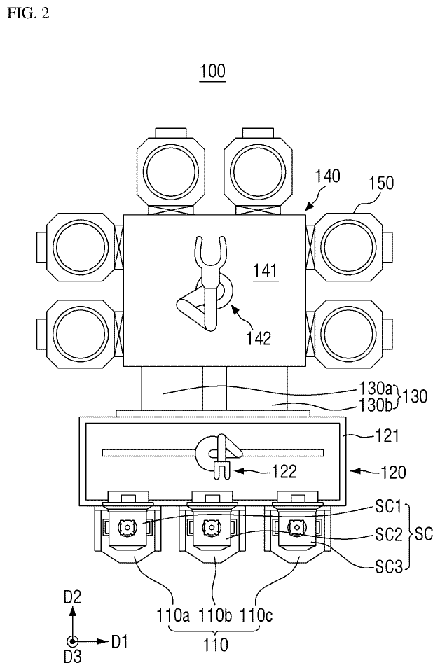

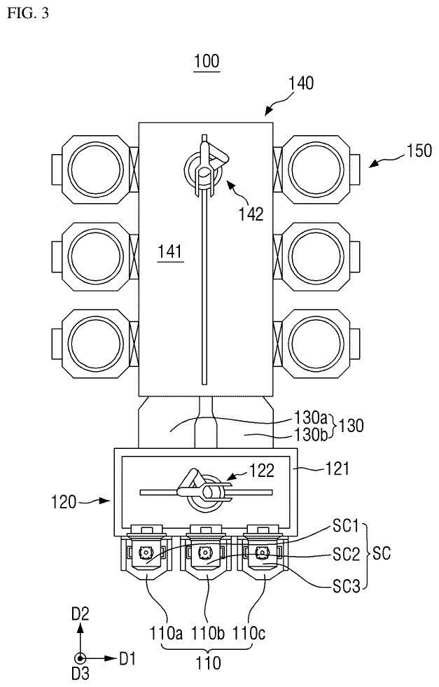

FIG. 1 is an exemplary plan view illustrating an internal structure of a semiconductor manufacturing facility according to the first embodiment. FIG. 2 is an exemplary plan view illustrating an internal structure of a semiconductor manufacturing facility according to the second embodiment. FIG. 3 is an exemplary plan view illustrating an internal structure of a semiconductor manufacturing facility according to the third embodiment.

A first direction D1 and a second direction D2 constitute a plane in a horizontal direction. For example, the first direction D1 may be a front-rear direction, and the second direction D2 may be a left-right direction. Alternatively, the first direction D1 may be a left-right direction, and the second direction D2 may be a front-rear direction. A third direction D3 is a height direction, and is a direction perpendicular to a plane constituted by the first direction D1 and the second direction D2. The third direction D3 may be a vertical direction.

According to FIGS. 1 to 3, a semiconductor manufacturing facility 100 may include a load port module 110, an index module 120, a load lock chamber 130, a transfer module 140, and a process chamber 150.

The semiconductor manufacturing facility 100 is a system that treats a substrate by using an etching process, a cleaning process, a deposition process, or the like. The semiconductor manufacturing facility 100 may include one process chamber, but may include a plurality of process chambers without being limited thereto. The plurality of process chambers may include the same kind of process chambers, but may include different kinds of process chambers without being limited thereto. When the semiconductor manufacturing facility 100 includes a plurality of process chambers, it may be provided as a multi-chamber substrate treating system.

The load port module 110 is provided to allow a container SC, on which a plurality of substrates are mounted, to be seated thereon. For example, the container SC may be a Front Opening Unified Pod (FOUP).

In the load port module 110, the container SC may be loaded or unloaded. Also, in the load port module 110, the substrate accommodated in the container SC may be loaded or unloaded.

When a loading or unloading target is the container SC, a container carrying device may load or unload the container SC on or from the load port module 110. In detail, the container SC gripped by the container carrying device may be seated on the load port module 110, thereby loading the container SC on the load port module 110. In addition, the container carrying device may unload the container SC from the load port module 110 by gripping the container SC seated on the load port module 110. Although not shown in FIGS. 1 to 3, the container carrying device may be an Overhead Hoist Transporter (OHT).

When the loading or unloading target is the substrate, a first transfer robot 122 may load or unload the substrate in or from the container SC seated on the load port module 110. In case of unloading of the substrate, when the container SC is seated on the load port module 110, the first transfer robot 122 may access the load port module 110 and then may take out the substrate from the container SC. In case of loading of the substrate, when the substrate is completely treated in the process chamber 150, the first transfer robot 122 may take out the substrate from the load lock chamber 130 and then carry the substrate into the container SC.

The load port module 110 may be disposed in front of the index module 120 as a plural number. For example, three load port modules 110a, 110b and 110c such as a first load port module 110a, a second load port module 110b and a third load port module 110c may be disposed in front of the index module 120.

When the plurality of load port modules 110 are disposed in front of the index module 120, the container SC seated on each load port module may be loaded with different types of objects. For example, when the first load port module 110a, the second load port module 110b and the third load port module 110c are disposed in front of the index module 120, a first container SC1 seated on the first load port module 110a may be loaded with a wafer-type sensor, a second container SC2 seated on the second load port module 110b may be loaded with the substrate, that is, a wafer, and a third container SC3 seated on the third load port module 110c may be loaded with consumable components such as a focus ring and an edge ring.

However, the present embodiment is not limited to the above example. The container SC seated on each load port module may be loaded with the same types of objects. Alternatively, among the plurality of load port modules, the containers seated on some load port modules may be loaded with the same type of objects, and the containers seated on some other load port modules may be loaded with different types of objects.

The index module 120 is disposed between the load port module 110 and the load lock chamber 130, and may be provided as an interface so that the substrate may be transferred between the container SC on the load port module 110 and the load lock chamber 130.

The index module 120 may include a first module housing 121 and a first transfer robot 122. The first transfer robot 122 is disposed inside the first module housing 121, and may transfer the substrate between the load port module 110 and the load lock chamber 130. An internal environment of the first module housing 121 is provided as an atmospheric pressure environment, and the first transfer robot 122 may be operated in the atmospheric pressure environment. One first transfer robot 122 may be provided in the first module housing 121, but the present disclosure is not limited thereto, and a plurality of first transfer robots 122 may be also provided.

Although not shown in FIGS. 1 to 3, the index module 120 may include a buffer chamber. The buffer chamber may temporarily store an untreated substrate before being transferred to the load lock chamber 130. Further, the buffer chamber may temporarily store a pre-treated substrate before being transferred to the container SC on the load port module 110. The buffer chamber may be provided on the other sidewalls except a sidewall adjacent to the load port module 110 or a sidewall adjacent to the load lock chamber 130, but the present disclosure is not limited thereto, and may be also provided on the sidewall adjacent to the load port module 110. Alternatively, the buffer chamber may be provided on the sidewall adjacent to the load lock chamber 130.

In the present embodiment, a front end module (FEM) may be provided on one side of the load lock chamber 130. The front end module (FEM) may include a load port module 110 and an index module 120, and for example, may be provided as an Equipment Front End Module (EFEM).

As described above, the load port module 110 may be provided in the semiconductor manufacturing facility 100 as a plural number. Referring to the examples of FIGS. 1 to 3, the plurality of load port modules may have a structure in which they are arranged in a horizontal direction D1, but the present disclosure is not limited thereto. The plurality of load port modules may also have a structure in which they are stacked in a vertical direction D3. When the plurality of load port modules are stacked in the vertical direction, the front end module may be provided as a vertically stacked EFEM.

The load lock chamber 130 may serve as a buffer chamber between an input port and an output port in the semiconductor manufacturing facility 100. That is, the load lock chamber 130 may serve to temporarily store the untreated substrate or the pre-treated substrate between the load port module 110 and the process chamber 150. Although not shown in FIGS. 1 to 3, the load lock chamber 130 may include a buffer stage for temporarily storing the substrate therein.

The load lock chamber 130 may be disposed between the index module 120 and the transfer module 140 as a plural number. For example, two load lock chambers 130a and 130b, such as a first load lock chamber 130a and a second load lock chamber 130b, may be disposed between the index module 120 and the transfer module 140.

The plurality of load lock chambers may be disposed in the same direction as an arrangement direction of the plurality of load port modules. Referring to the examples of FIGS. 1 to 3, the first load lock chamber 130a and the second load lock chamber 130b may be disposed in the same direction as the arrangement direction of the three load port modules 110a, 110b, and 110c between the index module 120 and the transfer module 140, i.e., in the horizontal direction D1. The first load lock chamber 130a and the second load lock chamber 130b may be provided in a mutually symmetrical single layered structure in which they are disposed to be spaced apart from each other in the horizontal direction.

However, the present embodiment is not limited to the above example. The plurality of load lock chambers may be disposed in a direction different from the arrangement direction of the plurality of load port modules. The first load lock chamber 130a and the second load lock chamber 130b may be disposed in a direction different from the arrangement direction of the three load port modules 110a, 110b and 110c between the index module 120 and the transfer module 140, i.e., in the vertical direction D3. The first load lock chamber 130a and the second load lock chamber 130b may be provided in a double-layered structure in which they are disposed to be spaced apart from each other in the vertical direction.

Any one of the first load lock chamber 130a and the second load lock chamber 130b may temporarily store the untreated substrate transferred from the index module 120 to the transfer module 140. Furthermore, the other load lock chamber may temporarily store the pre-treated substrate transferred from the transfer module 140 to the index module 120. However, the present disclosure is not limited to the above example. The first load lock chamber 130a and the second load lock chamber 130b may commonly serve as both a temporary storage of the untreated substrate and a temporary storage of the pre-treated substrate.

The load lock chamber 130 may change its inside to any one of a vacuum environment and an atmospheric pressure environment by using a gate valve or the like. In detail, when the first transfer robot 122 of the index module 120 loads the substrate into the load lock chamber 130 or the first transfer robot 122 unloads the substrate from the load lock chamber 130, the load lock chamber 130 may form its inside in an environment the same as or similar to an internal environment of the index module 120. Furthermore, when the second transfer robot 142 of the transfer module 140 loads the substrate into the load lock chamber 130 or the second transfer robot 142 unloads the substrate from the load lock chamber 130, the load lock chamber 130 may form its inside in an environment the same as or similar to an internal environment of the transfer module 140. Therefore, the load lock chamber 130 may prevent an inner air pressure state of the index module 120 or an inner air pressure state of the transfer module 140 from being changed.

The transfer module 140 is disposed between the load lock chamber 130 and the process chamber 150, and may be provided as an interface so that the substrate may be transferred between the load lock chamber 130 and the process chamber 150.

The transfer module 140 may include a second module housing 141 and a second transfer robot 142. The second transfer robot 142 is disposed inside the second module housing 141, and may transfer the substrate between the load lock chamber 130 and the process chamber 150. An internal environment of the second module housing 141 is provided as a vacuum environment, and the second transfer robot 142 may operate in the vacuum environment. One second transfer robot 142 may be provided inside the second module housing 141, but may be provided as a plural number without being limited thereto.

The transfer module 140 may be connected to the plurality of process chambers 150. To this end, the second module housing 141 may include a plurality of sides, and the second transfer robot 142 may be freely rotated through each side of the second module housing 141 so that the substrate may be loaded in the plurality of process chambers 150 or may be unloaded from the plurality of process chambers 150.

The process chamber 150 serves to treat the substrate. When the untreated substrate is provided, the process chamber 150 may treat the substrate and provide the pre-treated substrate to the load lock chamber 130 through the transfer module 140. A more detailed description of the process chamber 150 will be given later.

When the semiconductor manufacturing facility 100 includes the plurality of process chambers, the semiconductor manufacturing facility 100 may be formed in a structure having a cluster platform. For example, the plurality of process chambers may be disposed in a cluster manner based on the transfer module 140 as illustrated in FIG. 1, but the present embodiment is not limited thereto. When the semiconductor manufacturing facility 100 includes the plurality of process chambers, the semiconductor manufacturing facility 100 may be formed in a structure having a quad platform. For example, the plurality of process chambers may be disposed in a quad manner based on the transfer module 140 as illustrated in the example of FIG. 2. Alternatively, when the semiconductor manufacturing facility 100 includes the plurality of process chambers, the semiconductor manufacturing facility 100 may be formed in a structure having an in-line platform. For example, the plurality of process chambers may be disposed in an in-line manner based on the transfer module 140 as illustrated in the example of FIG. 3, and two different process chambers may be disposed in series while forming a corresponding relationship on both sides of the transfer module 140.

Although not shown in FIGS. 1 to 3, the semiconductor manufacturing facility 100 may further include a control device. The control device serves to control the entire operation of each module constituting the semiconductor manufacturing facility 100. For example, the control device may control the substrate transfer of the first transfer robot 122 or the second transfer robot 142, control a change in an internal environment of the load lock chamber 130 and control an overall substrate treating process of the process chamber 150.

The control device may include a processor for controlling each component constituting the semiconductor manufacturing facility 100, a network for wired or wireless communication with each component, one or more instructions related to a function or operation for controlling each component, a storage means for storing processing recipes including the instructions, various data, and the like. In addition, the control device may further include a user interface that includes an input means for allowing an operator to perform a command input manipulation or the like to manage the semiconductor manufacturing facility 100 and an output means for visualizing and displaying an actuation status of the semiconductor manufacturing facility 100. The control device may be provided as a computing device for data processing, analysis, and command transmission.

The instruction may be provided in the form of a computer program or an application. The computer program may include one or more instructions and thus may be stored in a computer-readable recording medium. The instruction may include a code generated by a compiler, a code capable of being executed by an interpreter, and the like. The storage means may be provided as one or more storage media selected from a flash memory, an HDD, an SSD, a card type memory, a RAM, an SRAM, a ROM, an EEPROM, a PROM, a magnetic memory, a magnetic disk and an optical disk.

Next, the process chamber 150 will be described. A surface of the process chamber 150 may be made of alumite formed with an anodized film, and an inside thereof may be configured to be air tight. The process chamber 150 may be provided in the semiconductor manufacturing facility 100 as a plural number, and the plurality of process chambers may be disposed to be spaced apart from each other around the transfer module 140, but the present disclosure is not limited thereto, and the process chamber 150 may be also provided in the semiconductor manufacturing facility 100 as a single number. The process chamber 150 may be provided in a cylindrical shape, but is not limited thereto, and may be provided in a shape other than the cylindrical shape.

As described above, the process chamber 150 may treat the substrate. Hereinafter, the process chamber 150 will be defined as the substrate treating apparatus and the internal structure of the process chamber 150 will be described.

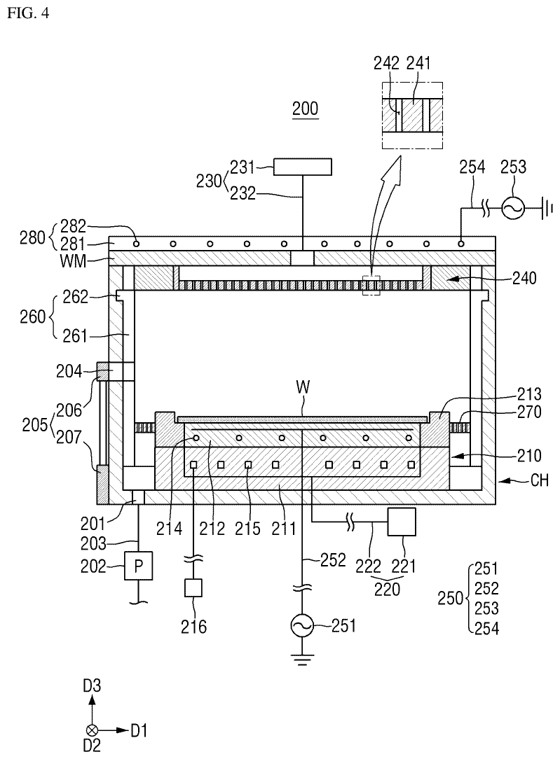

FIG. 4 is an exemplary cross-sectional view illustrating an internal structure of a substrate treating apparatus according to the first embodiment. According to FIG. 4, the substrate treating apparatus 200 may include a chamber housing CH, a substrate support unit 210, a cleaning gas supply unit 220, a process gas supply unit 230, a showerhead unit 240, a plasma generating unit 250, a liner unit 260, a baffle unit 270, a window module WM, and an antenna unit 280.

The substrate treating apparatus 200 may treat the substrate W by using plasma. The substrate treating apparatus 200 may treat the substrate W in a dry method. The substrate treating apparatus 200 may treat the substrate W, for example, in a vacuum environment. The substrate treating apparatus 200 may treat the substrate W by using an etching process, but is not limited thereto, and the substrate treating apparatus 200 may also treat the substrate W by using a deposition process or a cleaning process.

The chamber housing CH provides a space in which a process of treating the substrate W by using plasma, that is, a plasma process is executed. A surface of the chamber housing CH may be made of alumite formed with an anodized film, and an inside thereof may be configured to be air tight. The chamber housing CH may be provided in a cylindrical shape, but is not limited thereto, and may be provided in a shape other than the cylindrical shape. The chamber housing CH may have an exhaust hole 201 in a lower portion thereof.

The exhaust hole 201 may be connected to an exhaust line 203 on which a pump 202 is mounted. The exhaust hole 201 may discharge reaction by-products generated during the plasma process and a gas remaining inside the chamber housing CH to the outside of the chamber housing CH through the exhaust line 203. In this case, an inner space of the chamber housing CH may be decompressed.

An opening 204 may be formed to pass through a sidewall of the chamber housing CH. The opening 204 may be provided as a passage through which the substrate W enters and exits the chamber housing CH. The opening 204 may be configured to be automatically opened and closed by, for example, a door assembly 205.

The door assembly 205 may include an outer door 206 and a door driver 207. The outer door 206 may open and close the opening 204 on an outer wall of the chamber housing CH. The outer door 206 may be moved in the height direction D3 of the substrate treating apparatus 200 under the control of the door driver 207. The door driver 207 may operate using at least one element selected from a motor, a hydraulic cylinder and a pneumatic cylinder.

The substrate support unit 210 is installed in an inner lower zone of the chamber housing CH. The substrate support unit 210 may adsorb and support the substrate W by using an electro-static force. For example, the substrate support unit 210 may be provided as an electro-static chuck (ESC), but is not limited thereto. The substrate support unit 210 may support the substrate W by using various other methods such as vacuum and mechanical clamping.

When the substrate support unit 210 is provided as an electro-static chuck (ESC), the substrate support unit 210 may include a base plate 211 and a dielectric layer 212. The dielectric layer 212 is disposed on the base plate 211 and may adsorb and support the substrate W seated thereon. The base plate 211 may be formed of a material having excellent corrosion resistance and heat resistance. The base plate 211 may be provided as, for example, an aluminum body. The dielectric layer 212 may be formed of, for example, a ceramic material, and may be provided as a ceramic puck.

Although not shown in FIG. 4, the substrate support unit 210 may further include a bonding layer. The bonding layer may bond the base plate 211 to the dielectric layer 212. The bonding layer may include, for example, a polymer.

The ring structure 213 is provided to surround an outer edge zone of the dielectric layer 212. The ring structure 213 may serve to concentrate ions on the substrate W when the plasma process is performed inside the chamber housing CH. The ring structure 213 may be formed of a silicon material. For example, the ring structure 213 may be provided as a focus ring.

Although not shown in FIG. 4, the substrate treating apparatus 200 may further include an edge ring. The edge ring may be provided below or outside the focus ring. The edge ring may serve to prevent a side of the dielectric layer 212 from being damaged by plasma. The edge ring may be formed of an insulator material, for example, ceramic or quartz.

A heating member 214 and a cooling member 215 are provided to maintain the substrate W at a process temperature when the substrate treating process is performed inside the chamber housing CH. The heating member 214 may be installed inside the dielectric layer 212, and may be provided as a heating wire. The cooling member 215 may be installed inside the base plate 211, and may be provided as a cooling pipe through which a refrigerant moves. A cooling device (chiller) 216 may supply the refrigerant to the cooling member 215. The cooling device 216 may use cooling water as the refrigerant, but is not limited thereto, and may further use helium (He) gas. Alternatively, the cooling device 216 may use both cooling water and helium gas as the refrigerant. Meanwhile, the heating member 214 may not be provided inside the substrate support unit 210.

The cleaning gas supply unit 220 provides a cleaning gas to the dielectric layer 212 or the ring structure 213 to remove particles remaining in the dielectric layer 212 or the ring structure 213. For example, the cleaning gas supply unit 220 may provide nitrogen (N₂) gas as the cleaning gas.

The cleaning gas supply unit 220 may include a cleaning gas supply source 221 and a cleaning gas supply pipe 222. The cleaning gas supply pipe 222 may be connected to a space between the dielectric layer 212 and the ring structure 213. The cleaning gas supplied by the cleaning gas supply source 221 may move to a space between the dielectric layer 212 and the ring structure 213 through the cleaning gas supply pipe 222 to remove particles remaining in an edge portion of the dielectric layer 212 or an upper portion of the ring structure 213.

The process gas supply unit 230 provides a process gas to the inner space of the chamber housing CH. The process gas supply unit 230 may provide the process gas to the inner space of the chamber housing CH through a hole formed by passing through an upper cover of the chamber housing CH, that is, the window module WM, but is not limited thereto. The process gas supply unit 230 may also provide the process gas to the inner space of the chamber housing CH through a hole formed by passing through the sidewall of the chamber housing CH.

The process gas supply unit 230 may include a process gas supply source 231 and a process gas supply pipe 232. The process gas supply source 231 may provide a gas used for treating the substrate W as the process gas. The process gas supply source 231 may be provided as a single number in the substrate treating apparatus 200, but may be provided as a plural number without being limited thereto. When the process gas supply source 231 is provided in the substrate treating apparatus 200 as a plural number, the plurality of process gas supply sources 231 may provide the same type of process gas, but are not limited thereto, and may provide different types of process gases.

The showerhead unit 240 sprays the process gas provided from the process gas supply source 231 to the entire zone of the substrate W disposed in the inner space of the chamber housing CH. The showerhead unit 240 may be connected to the process gas supply source 231 through the process gas supply pipe 232.

The showerhead unit 240 is disposed in the inner space of the chamber housing CH, and may include a plurality of gas feeding holes 242. The plurality of gas feeding holes 242 may be formed to pass through a surface of a main body 241 in the vertical direction D3. The plurality of gas feeding holes 242 may be formed to be spaced apart from each other at a constant interval on the main body 241. The showerhead unit 240 may uniformly spray the process gas to the entire zone of the substrate W through the plurality of gas feeding holes 242.

The showerhead unit 240 may be installed inside the chamber housing CH to face the substrate support unit 210 in the vertical direction D3. The showerhead unit 240 may be provided to have a larger diameter than the dielectric layer 212, but is not limited thereto. The showerhead unit 240 may be provided to have the same diameter as that of the dielectric layer 212. The showerhead unit 240 may be formed of a silicon material, but is not limited thereto. The showerhead unit 240 may be also formed of a metal material.

Although not shown in FIG. 4, the showerhead unit 240 may be divided into a plurality of units. For example, the showerhead unit 240 may be divided into three modules such as a first head module, a second head module and a third head module. The first head module may be disposed at a position corresponding to a center zone of the substrate W. The second head module may be disposed to surround an outer edge of the first head module. The second head module may be disposed at a position corresponding to a middle zone of the substrate W. The third head module may be disposed to surround an outer edge of the second head module. The third head module may be disposed at a position corresponding to an edge zone of the substrate W.

The plasma generating unit 250 generates plasma from a gas remaining in a discharge space. In this case, the discharge space is the inner space of the chamber housing CH, and may be a space formed between the showerhead unit 240 and the window module WM. Alternatively, the discharge space may be a space formed between the substrate support unit 210 and the showerhead unit 240. When the discharge space is the space formed between the substrate support unit 210 and the showerhead unit 240, the discharge space may be divided into a plasma zone and a process zone. The plasma zone may be formed to be higher than the process zone.

The plasma generating unit 250 may generate plasma in the discharge space by using an inductively coupled plasma (ICP) source. For example, the plasma generating unit 250 may generate plasma in the discharge space by using the substrate support unit 210 and the antenna unit 280 as a first electrode (lower electrode) and a second electrode (upper electrode), respectively, but the present embodiment is not limited thereto.

The plasma generating unit 250 may generate plasma in the discharge space by using a capacitively coupled plasma (CCP) source. For example, the plasma generating unit 250 may generate plasma in the discharge space by using the substrate support unit 210 and the showerhead unit 240 as a first electrode (lower electrode) and a second electrode (upper electrode), respectively. The case that the plasma generating unit 250 is provided as the ICP source will be described herein. The case that the plasma generating unit 250 is provided as the CCP source will be described later.

The plasma generating unit 250 may include a first high frequency power source 251, a first transmission line 252, a second high frequency power source 253, and a second transmission line 254.

The first high frequency power source 251 applies RF power to the first electrode. The first high frequency power source 251 may serve as a plasma source for generating plasma in the chamber housing CH but is not limited thereto. The first high frequency power source 251 may serve to control characteristics of plasma in the chamber housing CH together with the second high frequency power source 253.

The first high frequency power source 251 may be provided in the substrate treating apparatus 200 as a plural number. In this case, the plasma generating unit 250 may include a first matching network electrically connected to each of the first high frequency power sources. The first matching network may serve to match the frequency powers of different magnitudes and apply them to the first electrode when the frequency powers of different magnitudes are input from the plurality of first high frequency power sources.

The first transmission line 252 may connect the first electrode to GND. The first high frequency power source 251 may be installed on the first transmission line 252, but is not limited thereto. The first transmission line 252 may connect the first electrode to the first high frequency power source 251. For example, the first transmission line 252 may be provided as an RF rod.

The second high frequency power source 253 applies RF power to the second electrode. The second high frequency power source 253 may serve to control characteristics of plasma in the chamber housing CH. For example, the second high frequency power source 253 may serve to control ion bombardment energy in the chamber housing CH.

The second high frequency power source 253 may be provided in the substrate treating apparatus 200 as a plural number. In this case, the plasma generating unit 250 may include a second matching network electrically connected to each of the second high frequency power sources. The second matching network may serve to match the frequency powers and apply them to the second electrode when frequency powers of different magnitudes are input from the plurality of second high frequency power sources.

The second transmission line 254 connects the second electrode to the GND. The second high frequency power source 253 may be installed on the second transmission line 254.

The liner unit 260 may be defined as a wall liner, and protects the inside of the chamber housing CH from arc discharge occurring during a process of exciting a process gas or impurities generated during the substrate treating process. The liner unit 260 may be formed to cover an inner wall of the chamber housing CH.

The liner unit 260 may include a support ring 262 on an upper portion of a body 261. The support ring 262 may be protruded from the upper portion of the body 261 in an outward direction D1, and may serve to fix the body 261 to the chamber housing CH.

The baffle unit 270 serves to exhaust an unreacted gas or a process by-product of plasma inside the chamber housing CH to the outside. The baffle unit 270 may be installed in a space between the substrate support unit 210 and the inner wall (or the liner unit 260) of the chamber housing CH, and may be installed to be adjacent to the exhaust hole 201. The baffle unit 270 may be provided in a ring shape between the substrate support unit 210 and the inner wall of the chamber housing CH.

The baffle unit 270 may include a plurality of slot holes passing through a body in the vertical direction D3 to control a flow of the process gas in the chamber housing CH. The baffle unit 270 may be formed of a material having etch resistance to minimize damage or deformation by radicals or the like in the inner space of the chamber housing CH, in which plasma is generated. For example, the baffle unit 270 may be formed to include quartz.

The window module WM serves as an upper cover of the chamber housing CH, which seals the inner space of the chamber housing CH. The window module WM may be provided separately from the chamber housing CH, but is not limited thereto, and may be also provided integrally with the chamber housing CH. The window module WM may be formed of a dielectric window made of an insulating material. For example, the window module WM may be formed of alumina. When the plasma process is performed in the inner space of the chamber housing CH, the window module WM may include a coating film on a surface to suppress occurrence of particles.

The antenna unit 280 serves to excite the process gas into plasma by generating a magnetic field and an electric field inside the chamber housing CH. The antenna unit 280 may operate using RF power supplied from the second high frequency power source 253. The antenna unit 280 may be provided on the upper portion of the chamber housing CH. For example, the antenna unit 280 may be provided on the window module WM, but is not limited thereto, and the antenna unit 280 may be provided on the sidewall of the chamber housing CH.

The antenna unit 280 may include an antenna 282 inside or on a surface of the body 281. The antenna 282 may be provided to form a closed loop by using a coil. The antenna 282 may be formed in a spiral shape along a width direction D1 of the chamber housing CH or other various shapes.

The antenna unit 280 may be formed to have a planar type, but is not limited thereto, and the antenna unit 280 may be formed to have a cylindrical type. When the antenna unit 280 is formed to have a planar type, it may be provided on the upper portion of the chamber housing CH. When the antenna unit 280 is formed to have a cylindrical type, it may be provided to surround the outer sidewall of the chamber housing CH.

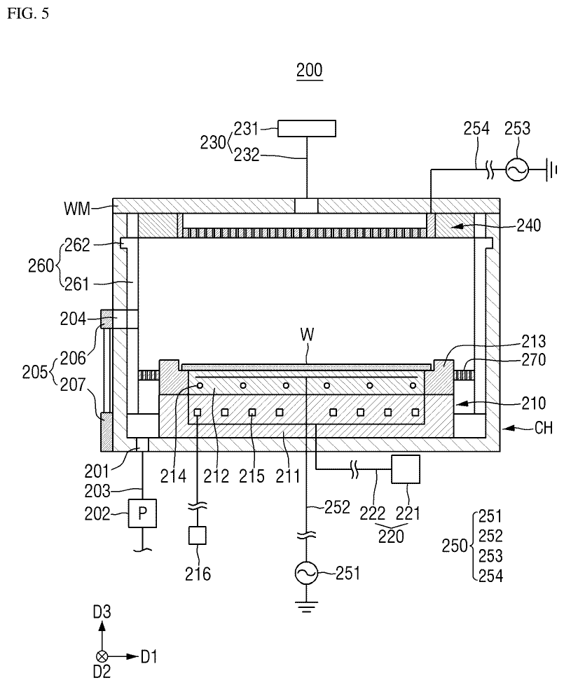

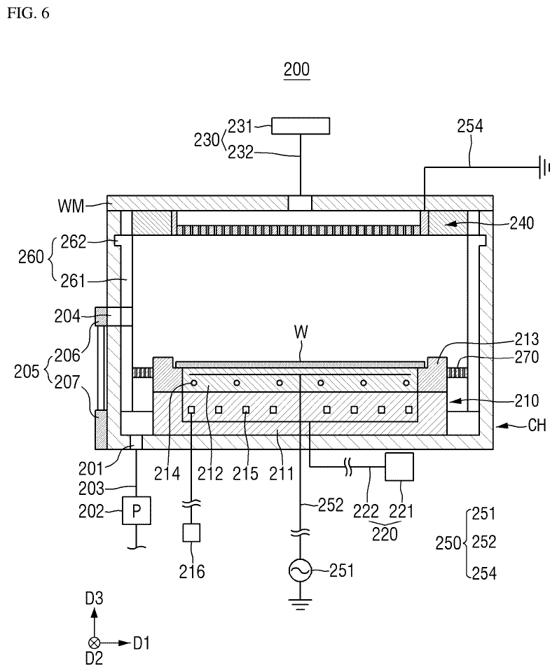

The case that the plasma generating unit 250 is provided as an ICP source has been described with reference to FIG. 4. Hereinafter, the case that the plasma generating unit 250 is provided as a CCP source will be described with reference to FIGS. 5 and 6. Hereinafter, a description of redundant portions as compared with the case of FIG. 4 will be omitted, and only portions corresponding to differences therefrom will be described.

FIG. 5 is an exemplary cross-sectional view illustrating an internal structure of a substrate treating apparatus according to the second embodiment. FIG. 6 is an exemplary cross-sectional view illustrating an internal structure of a substrate treating apparatus according to the third embodiment.

Referring to FIGS. 5 and 6, the substrate treating apparatus 200 may include a chamber housing CH, a substrate support unit 210, a cleaning gas supply unit 220, a process gas supply unit 230, a showerhead unit 240, a plasma generating unit 250, a liner unit 260, a baffle unit 270, and a window module WM. That is, the substrate treating apparatus 200 of FIGS. 5 and 6 may not include an antenna unit 280 as compared with the substrate treating apparatus 200 of FIG. 4.

The plasma generating unit 250 may include a first high frequency power source 251, a first transmission line 252, a second high frequency power source 253, and a second transmission line 254, but is not limited thereto. As shown in FIG. 6, the plasma generating unit 250 may include a first high frequency power source 251, a first transmission line 252, and a second transmission line 254. That is, the plasma generating unit 250 of FIG. 6 may not include a second high frequency power source 253 as compared with the plasma generating unit 250 of FIG. 5.

In case of the example according to FIG. 4, the second transmission line 254 may be connected to the antenna 282 of the antenna unit 280. The second high frequency power source 253 may apply RF power to the antenna 282 of the antenna unit 280. In case of the example according to FIG. 5, the second transmission line 254 may be connected to the main body 241 of the showerhead unit 240. The second high frequency power source 253 may apply RF power to the main body 241 of the showerhead unit 240.

In case of the example according to FIG. 5, the second high frequency power source 253 may be installed on the second transmission line 254. In case of the example according to FIG. 6, the second high frequency power source 253 may not be installed on the second transmission line 254. When the second high frequency power source 253 is installed on the second transmission line 254, the plasma generating unit 250 may apply a multi-frequency to the substrate treating apparatus 200.

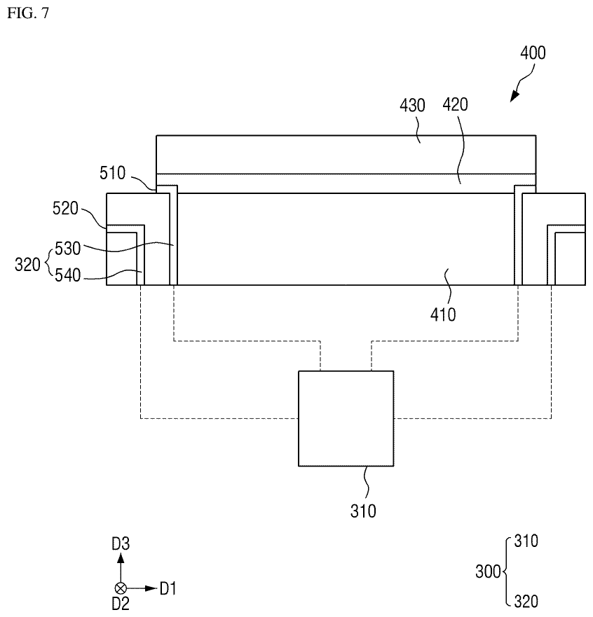

Next, a gas spraying apparatus will be described. FIG. 7 is an exemplary view illustrating a gas spraying apparatus according to the first embodiment of the present disclosure. Referring to FIG. 7, the gas spraying apparatus 300 may include a gas supply unit 310 and a gas supply line 320.

First, an electro-static chuck (ESC) 400 will be defined. The electro-static chuck 400 may be configured to include a first plate 410, a second plate 420, and an adhesive layer 430. The first plate 410 may be formed of a metal material. For example, the first plate 410 may be formed of an aluminum material. The first plate 410 may be provided as the base plate 211. The second plate 420 may be formed of a ceramic material. For example, the second plate 420 may be provided as a ceramic puck. The second plate 420 may be provided as the dielectric layer 212.

The adhesive layer 430 may be bonded to the first plate 410 and the second plate 420. The second plate 420 may be installed on the first plate 410 through the adhesive layer 430. The adhesive layer 430 may be formed between the first plate 410 and the second plate 420.

The electro-static chuck 400 is responsible for fixing the substrate W and heat balance in the chamber housing CH during the substrate treating process. Accordingly, the electro-static chuck 400 may play an important role in yield of a semiconductor product.

However, the electro-static chuck 400 is always exposed to the process gas, which may cause structural and functional problems due to the process gas.

First, when a polymer generated in the substrate treating process is accumulated on a surface of the electro-static chuck 400, a problem may occur in heat efficiency. This may reduce efficiency in heat balance, which is a main function of the electro-static chuck 400.

Second, when the polymer is accumulated on the surface of the electro-static chuck 400, arcing may be caused. When arcing occurs, the yield of the semiconductor product may be deteriorated due to a defect of the semiconductor product, and lifespan of the electro-static chuck 400 may be reduced.

Third, the process gas may etch the adhesive layer 430. When the adhesive layer 430 is etched, heat conductivity of the electro-static chuck 400 may be reduced. This may negatively affect the yield of the semiconductor product.

The gas spraying apparatus 300 may prevent process by-products from being deposited on parts inside the substrate treating apparatus 200. The gas spraying apparatus 300 may prevent the process gas from approaching the parts inside the substrate treating apparatus 200. For example, the gas spraying apparatus 300 may prevent the polymer from being deposited on the electro-static chuck 400 and prevent the process gas from approaching the electro-static chuck 400.

The gas supply unit 310 may supply gas to the electro-static chuck 400. The gas supply unit 310 may supply the gas to the electro-static chuck 400 through the gas supply line 320. The gas provided by the gas supply unit 310 may prevent the polymer from being deposited on the electro-static chuck 400. The gas provided by the gas supply unit 310 may prevent the process gas from approaching the electro-static chuck 400. The gas provided by the gas supply unit 310 may not react with the process gas. For example, the gas provided by the gas supply unit 310 may be an inert gas (or an inactive gas).

The gas supply line 320 may be connected to the gas supply unit 310. The gas supply line 320 may move the gas provided by the gas supply unit 310. The gas supply line 320 may be installed inside the electro-static chuck 400. The gas supply line 320 may be installed inside the first plate 410.

The gas supply line 320 may form an outlet on a side of the electro-static chuck 400. The outlet of the gas supply line 320 may be formed between the first plate 410 and the adhesive layer 420. Also, the outlet of the gas supply line 320 may be formed on a side of the first plate 410. Hereinafter, the outlet of the gas supply line 320 formed between the first plate 410 and the adhesive layer 420 is defined as a first outlet 510, and the outlet of the gas supply line 320 formed on the side of the first plate 410 is defined as a second outlet 520.

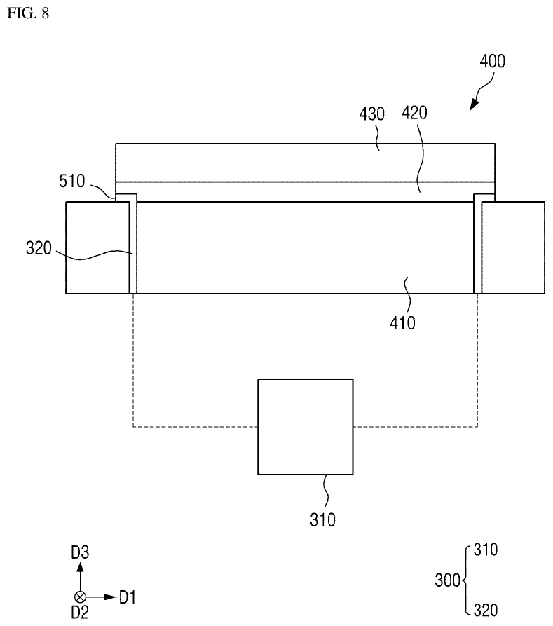

However, the present disclosure is not limited to the above example, and the outlet of the gas supply line 320 may be formed only either between the first plate 410 and the adhesive layer 420 or on the side of the first plate 410. For example, referring to FIG. 8, the outlet of the gas supply line 320 may be formed between the first plate 410 and the adhesive layer 420, and may not be formed on the side of the first plate 410. That is, the outlet of the gas supply line 320 may include only the first outlet 510. FIG. 8 is an exemplary view illustrating a gas spraying apparatus according to the second embodiment of the present disclosure.

The description will be given by referring back to FIG. 7.

The gas supply line 320 may be formed as a plural number. For example, the gas supply line 320 may include a first gas supply pipe 530 and a second gas supply pipe 540. The first gas supply pipe 530 may connect the gas supply unit 310 with the first outlet 510 of the gas supply line 320. The second gas supply pipe 540 may connect the gas supply unit 310 with the second outlet 520 of the gas supply line 320.

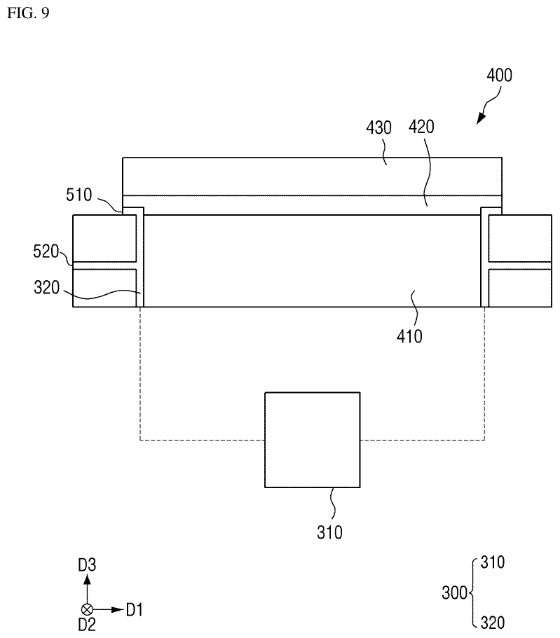

However, the present disclosure is not limited to the above example, and the gas supply line 320 may be formed as a single number. For example, referring to FIG. 9, the first outlet 510 of the gas supply line 320 may be connected to an end portion of the gas supply line 320. The second outlet 520 of the gas supply line 320 may be branched from a middle point of the gas supply line 320. FIG. 9 is an exemplary view illustrating a gas spraying apparatus according to the third embodiment of the present disclosure.

When the gas supply line 320 is formed as a plural number, non-simultaneous control or independent control is possible. When the gas supply line 320 includes a first gas supply pipe 530 and a second gas supply pipe 540, the gas provided by the first gas supply pipe 530 and the gas provided by the second gas supply pipe 540 may be sprayed at different times. Alternatively, one of the gas provided by the first gas supply pipe 530 and the gas provided by the second gas supply pipe 540 may be sprayed with a time difference from the other gas. The case that the gas is provided through the first gas supply pipe 530 and the case that the gas is provided through the second gas supply pipe 540 may be independently controlled.

On the other hand, when the gas supply line 320 is formed as a single number, simultaneous control is possible. That is, the gas provided through the first outlet 510 and the gas provided through the second outlet 520 may be sprayed at the same time.

The outlet of the gas supply line 320 may further include at least one third outlet in addition to the first outlet 510 and the second outlet 520. The third outlet may be formed between the adhesive layer 430 and the second plate 420. Alternatively, the third outlet may be formed on the side of the second plate 420. Otherwise, the third outlet may be formed between the adhesive layer 430 and the second plate 420 and on a side of the second plate 420, respectively.

The description will be given by referring back to FIG. 7.

The first and second outlets 510 and 520 of the gas supply line 320 may be formed at different levels. In this case, being formed at different levels means being formed at different heights. The first outlet 510 of the gas supply line 320 may be formed at a higher level than the second outlet 520 of the gas supply line 320. That is, the first outlet 510 of the gas supply line 320 may be formed at a higher position than the second outlet 520 of the gas supply line 320 in the height direction D3 of the electro-static chuck 400.

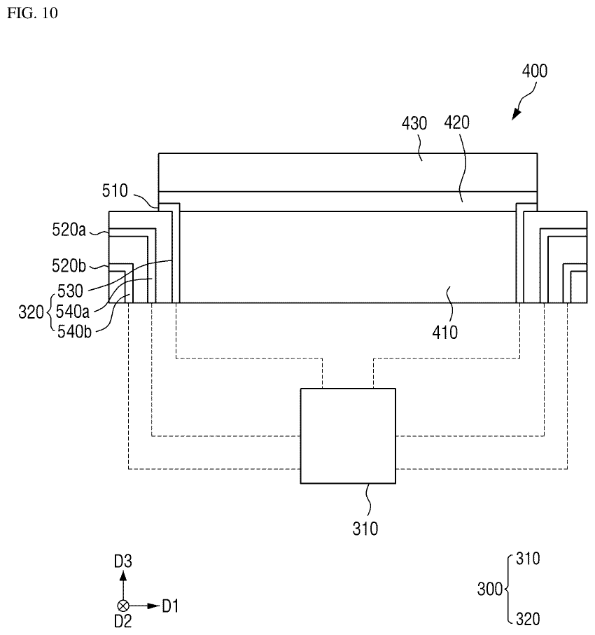

The second outlet 520 of the gas supply line 320 may be configured as a single number, but is not limited thereto and may be also configured as a plural number. Referring to FIG. 10, the second outlet 520 of the gas supply line 320 may include an (a)th outlet 520a and a (b)th outlet 520b. FIG. 10 is an exemplary view illustrating a gas spraying apparatus according to the fourth embodiment of the present disclosure.

The (a)th outlet 520a may be formed at a different level from the (b)th outlet 520b. The (a)th outlet 520a may be formed at a higher level than the (b)th outlet 520b. The (a)th outlet 520a and the (b)th outlet 520b may be arranged side by side in the third direction D3. That is, the (a)th outlet 520a and the (b)th outlet 520b may be arranged in the height direction of the first plate 410, but are not limited thereto, and the (a)th outlet 520a may be formed at the same level as the (b)th outlet 520b. The (a)th outlet 520a and the (b)th outlet 520b may be arranged side by side in the first direction D1. Alternatively, the (a)th outlet 520a and the (b)th outlet 520b may be arranged side by side in the second direction D2. That is, the (a)th outlet 520a and the (b)th outlet 520b may be arranged along the circumference of the first plate 410.

The (a)th outlet 520a and the (b)th outlet 520b may be connected to their respective gas supply pipes different from each other. The (a)th outlet 520a may be connected to an (a)th gas supply pipe 540a. The (a)th outlet 520a may be connected to the gas supply unit 310 through the (a)th gas supply pipe 540a. The (b)th outlet 520b may be connected to the gas supply unit 310 through a (b)th gas supply pipe 540b.

The (a)th and (b)th outlets 520a and 520b may be connected to the same gas supply pipe. That is, the (a)th and (b)th outlets 520a and 520b may be connected to the second gas supply pipe 520. The (a)th outlet 520a may be connected to an end portion of the second gas supply pipe 520. The (b)th outlet 520b may be branched from a middle point of the second gas supply pipe 520.

The description will be given by referring back to FIG. 7.

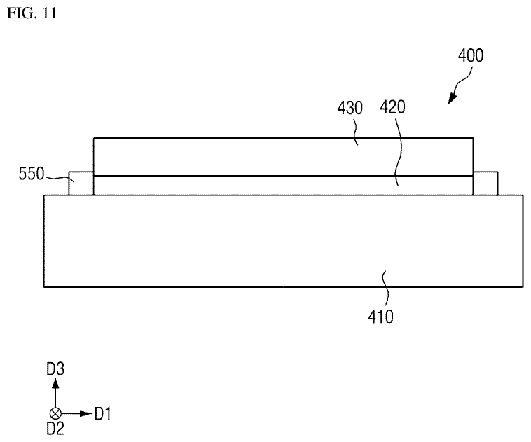

The electro-static chuck 400 may include an elastic body that is in close contact with an upper surface of the first plate 410 and a side of the adhesive layer 430. Referring to FIG. 11, the elastic body 550 may be an O-ring having a circular cross-section. Although not shown in FIG. 11, the elastic body 550 may be an elastic band (E-band) having a rectangular cross-section.

The elastic body 550 may prevent the process gas from approaching the adhesive layer 430. The elastic body 550 may prevent the polymer from being deposited on the upper surface of the first plate 410 or the side of the adhesive layer 430 due to the process gas. However, even though the elastic body 550 is formed to be in close contact with the upper surface of the first plate 410 and the side of the adhesive layer 430, a gap may be formed between the first plate 410 and the cover member 550 or between the adhesive layer 430 and the cover member 550 due to elastic characteristics of the elastic body 550. Also, as the substrate treating process is performed several times, the elastic body 550 may be worn by radicals and the like. For this reason, the gap may be formed between the first plate 410 and the cover member 550 or between the adhesive layer 430 and the cover member 550.

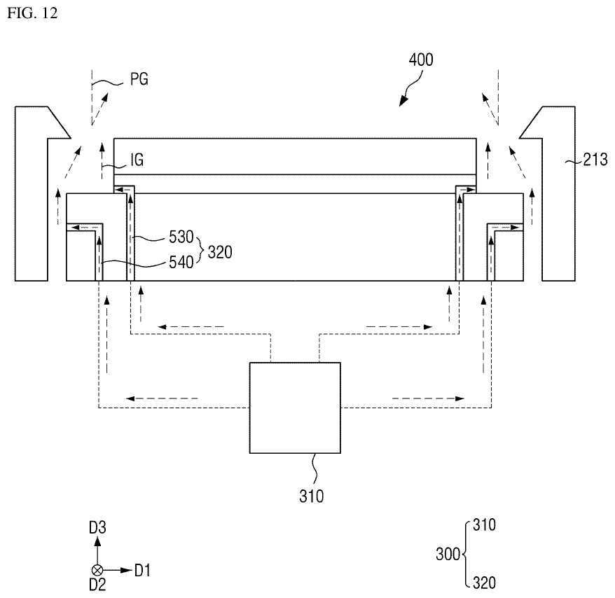

The gas supply unit 310 may spray the inert gas through the gas supply line 320. Referring to FIG. 12, the inert gas IG may move to the first outlet 510 and the second outlet 520 along the gas supply line 320. The inert gas IG may flow into the inner space of the chamber housing CH through the first outlet 510 and the second outlet 520. The inert gas IG may move upward in the inner space of the chamber housing CH.

The gas spraying apparatus 300 may prevent a process gas PG or a process by-product from being permeated into a space between the electro-static chuck 400 and the ring structure 213 through the above-described movement of the inert gas IG. The gas spraying apparatus 300 may prevent the polymer from being deposited on surfaces of the first plate 410 and the adhesive layer 430 through the inert gas IG. FIG. 11 is a first exemplary view illustrating an effect of a gas spraying apparatus according to the first embodiment of the present disclosure. FIG. 12 is a second exemplary view illustrating an effect of a gas spraying apparatus according to the first embodiment of the present disclosure.

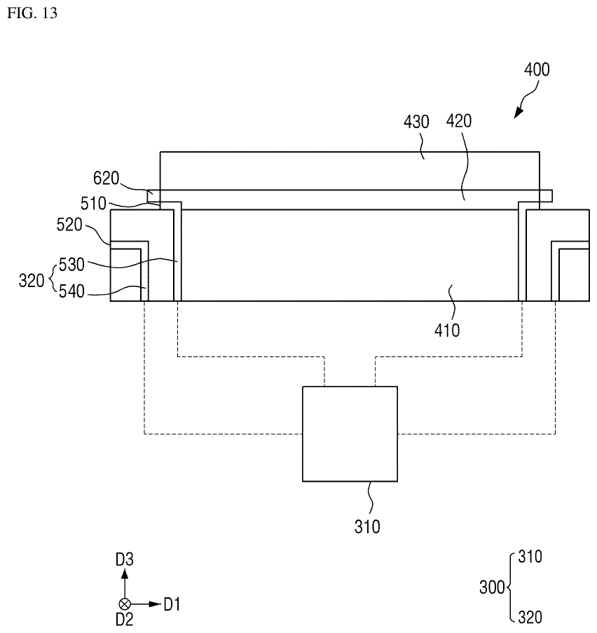

The electro-static chuck 400 may further include a coating layer 620. Referring to FIG. 13, the coating layer 620 may be formed on the surface of the adhesive layer 430. The surface of the adhesive layer 430 on which the coating layer 620 is formed may be a surface, which is exposed to the outside, among several surfaces of the adhesive layer 430. The surface of the adhesive layer 430 on which the coating layer 620 is formed may be a side among several surfaces of the adhesive layer 430.

Even though the inert gas is sprayed through the first outlet 510 and the second outlet 520 during the substrate treating process, there may be a case that permeation of the process gas is not completely prevented. When the coating layer 620 is formed on the surface of the adhesive layer 430, which is exposed to the outside, the adhesive layer 430 may be prevented from being deformed by the process gas, and the polymer may be prevented from being deposited on the adhesive layer 430. The coating layer 620 may be formed of a material that does not react with the process gas.

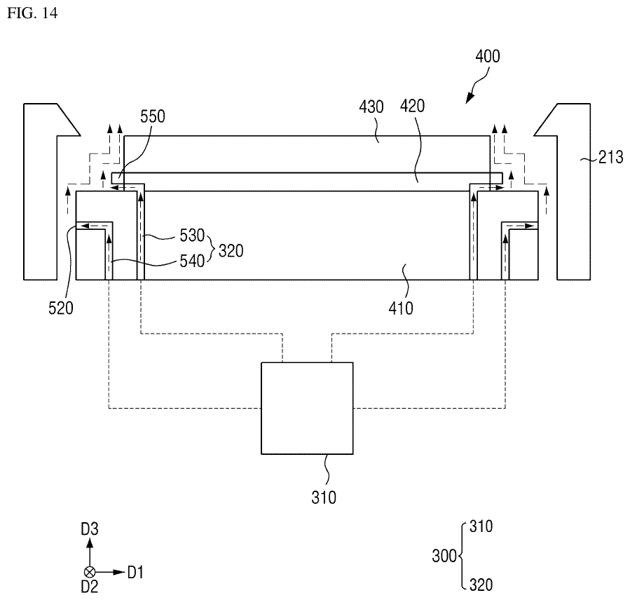

Also, referring to FIG. 14, the inert gas IG discharged through the first outlet 510 may move to the inner space of the chamber housing CH after passing through the space between the first plate 410 and the coating layer 620. The inert gas IG discharged through the first outlet 510 and the inert gas IG discharged through the second outlet 520 may prevent the polymer from being deposited on and around the surface of the coating layer 620. FIG. 13 is a first exemplary view illustrating a gas spraying apparatus according to the fifth embodiment of the present disclosure. FIG. 14 is a second exemplary view illustrating a gas spraying apparatus according to the fifth embodiment of the present disclosure.

The gas spraying apparatus 300 may be installed in the substrate treating apparatus 200. The gas spraying apparatus 300 may be installed in the substrate treating apparatus 200 separately from the cleaning gas supply unit 220, but is not limited thereto. The gas spraying apparatus 300 may include a cleaning gas supply unit 220 and may be also installed in the substrate treating apparatus 200. In this case, the first outlet 510 and the second outlet 520 of the gas supply line 320 may be connected to the cleaning gas supply pipe 222.

The gas spraying apparatus 300 may prevent the process gas from approaching or remaining on the surface of the electro-static chuck 400 to prevent the polymer from being accumulated. The gas spraying apparatus 300 may spray the gas by installing a flow path inside or around the electro-static chuck 400, thereby blocking the access of the process gas. The gas spraying apparatus 300 may remove the polymer around the electro-static chuck 400 to prevent arcing and resolve a yield problem of the semiconductor product. The gas spraying apparatus 300 may increase durability of the semiconductor product by preventing degradation of the adhesive layer 430 due to the process gas.

In the gas spraying apparatus 300, a flow path and an outlet may be installed in the first plate 410 so that the inert gases may flow, whereby the process gas may be prevented from approaching or remaining on the surface of the electro-static chuck 400. The outlet of the flow path may be installed at a side portion of the first plate 410 and a lower end portion of the adhesive layer 430. As a result, the process gas may be prevented from approaching the first plate 410 and the adhesive layer 430. The outlet of the flow path may be made in a portion other than the first plate 410 as needed.

When the process gas is prevented from approaching the electro-static chuck 400, the polymer may be prevented from being deposited on the surface of the electro-static chuck 400. The polymer is a factor that may negatively affect the yield of the semiconductor product and thus should be necessarily removed.

When the polymer is prevented from being accumulated, degradation of heat transfer capability due to the use time of the electro-static chuck 400 may be reduced. When the heat transfer capability is maintained, the use time of the electro-static chuck 400 may be increased, whereby substantial durability may be increased.

The polymer accumulated on the surface of the electro-static chuck 400 may cause arcing by being bonded to the surface of the substrate W during the process. Therefore, when the polymer is prevented from being accumulated on the surface of the electro-static chuck 400, the risk of arcing may be reduced.

When the process gas is prevented from approaching the adhesive layer 430, the adhesive layer 430 may be prevented from being degraded. This may increase durability of the electro-static chuck 400 and maintain heat efficiency, thereby increasing lifespan of the substrate treating apparatus 200.

Although the embodiments of the present disclosure have been described with reference to the accompanying drawings, it will be apparent to those skilled in the art that the present disclosure can be embodied in other specific forms without departing from the technical concepts and characteristics of the present disclosure. Thus, the above-described embodiments are to be considered in all respects as illustrative and not restrictive.

What is claimed is:

1. A substrate treating apparatus comprising:
a chamber housing providing a space in which a substrate is treated;
an electro-static chuck supporting the substrate;
a showerhead unit providing a first gas to the space;
a plasma generating unit generating plasma for treating the substrate by using the first gas; and
a gas spraying apparatus for spraying a second gas from a surface of the electro-static chuck to an inner space of the chamber housing,
wherein the electro-static chuck includes:
a first plate;
a second plate disposed on the first plate; and
an adhesive layer bonding the first plate and the second plate to each other, and
the gas spraying apparatus sprays the second gas through an outlet formed between the first plate and the adhesive layer.

2. The substrate treating apparatus of claim 1, wherein the gas spraying apparatus further sprays the second gas through an outlet formed on a surface of the first plate.

3. The substrate treating apparatus of claim 1, wherein the second gas is an inert gas.

4. The substrate treating apparatus of claim 1, wherein the second gas is a gas that does not react with the first gas.

5. The substrate treating apparatus of claim 1, wherein the gas spraying apparatus includes:
a gas supply unit providing the second gas; and
a gas supply line connected to the gas supply unit, moving the second gas and including the first outlet.

6. The substrate treating apparatus of claim 5, wherein the gas supply line further includes a second outlet formed on a surface of the first plate.

7. The substrate treating apparatus of claim 6, wherein the gas supply line includes:
a first gas supply pipe connected to the first outlet inside the first plate; and
a second gas supply pipe connected to the second outlet inside the first plate.

8. The substrate treating apparatus of claim 6, wherein the gas supply line is connected to the first outlet inside the first plate, and
the second outlet is connected to a line branched from the gas supply line.

9. The substrate treating apparatus of claim 6, wherein the second outlet is formed as a plural number.

10. The substrate treating apparatus of claim 9, wherein the plurality of second outlets are arranged in a height direction of the first plate.

11. The substrate treating apparatus of claim 9, wherein the plurality of second outlets are arranged along a circumference of the first plate.

12. The substrate treating apparatus of claim 1, wherein the gas spraying apparatus sprays the second gas while the substrate is being treated.

13. The substrate treating apparatus of claim 1, wherein the electro-static chuck further includes a coating layer formed on a surface exposed to the outside of the adhesive layer.

14. The substrate treating apparatus of claim 13, wherein the coating layer is formed of a material that does not react with the first gas.

15. A gas spraying apparatus provided in a substrate treating apparatus together with an electro-static chuck including a first plate, a second plate disposed on the first plate, and an adhesive layer bonding the first plate and the second plate to each other, the gas spraying apparatus comprising:
a gas supply unit providing a second gas different from a first gas used to treat the substrate; and
a gas supply line connected to the gas supply unit, moving the second gas,
wherein the gas spraying apparatus sprays the second gas to an inner space of the substrate treating apparatus through an outlet formed between the first plate and the adhesive layer.

16. The gas spraying apparatus of claim 15, further spraying the second gas through an outlet formed on a surface of the first plate.

17. The gas spraying apparatus of claim 15, wherein the second gas is an inert gas.

18. The gas spraying apparatus of claim 15, wherein the second gas is a gas that does not react with the first gas.

19. The gas spraying apparatus of claim 15, wherein the gas spraying apparatus is used when the substrate is treated using plasma.

20. A substrate treating apparatus comprising:
a chamber housing providing a space in which a substrate is treated;
an electro-static chuck supporting the substrate;
a showerhead unit providing a first gas to the space;
a plasma generating unit generating plasma for treating the substrate by using the first gas; and
a gas spraying apparatus for spraying a second gas from a surface of the electro-static chuck to an inner space of the chamber housing,
wherein the electro-static chuck includes:
a first plate;
a second plate disposed on the first plate; and
an adhesive layer bonding the first plate and the second plate to each other,
the gas spraying apparatus includes:
a gas supply unit providing the second gas; and
a gas supply line connected to the gas supply unit, moving the second gas and including a first outlet formed between the first plate and the adhesive layer and a second outlet formed on a surface of the first plate,
the gas spraying apparatus sprays the second gas through the first outlet and the second outlet, and
the second gas is an inert gas.
